(19) United States
(12) Patent Application Publication
(10) Pub. No.: US 2011/0195552 A1
(43) Pub. Date: Aug. 11, 2011

(54) METHOD FOR MANUFACTURING SEMICONDUCTOR DEVICE

(75) Inventor: Takayuki KANDA, Tokyo (JP)

(73) Assignee: ELPIDA MEMORY, INC., Tokyo (JP)

(21) Appl. No.: 12/960,879

(22) Filed: Dec. 6, 2010

(30) Foreign Application Priority Data
Feb. 8, 2010 (JP) 2010-025520

(51) Int. Cl. H01L 21/8242

(52) U.S. Cl. 438/239; 257/E21.646

(57) ABSTRACT

A semiconductor device includes a transistor. A gate insulating film of the transistor contains oxygen and nitrogen atoms. The gate insulating film does not contain the nitrogen atoms in a first face thereof being in a contact with the semiconductor layer, and in a second face thereof being in a contact with the gate electrode. A concentration peak of the nitrogen atoms appears between the first and second faces in the gate insulating film.

This application is based upon and claims the benefit of priority from Japanese Patent Application No. 2010-025520, filed on Feb. 8, 2010, the disclosure of which is incorporated herein in its entirety by reference.

### TECHNIQUE FIELD

The invention relates to a method for manufacturing a semiconductor device.

### RELATED ART

Conventionally, a film containing oxygen and nitrogen atoms has been employed as a gate insulating film.

Japanese Patent Laid-Open No. 2009-252895, No. 2009-224812, and No. 2009-200211 disclose examples in which a SiON film is used as the gate insulating film.

In a conventional method of forming the gate insulating film, a silicon oxide film is first formed on a surface of a silicon substrate, and, then, a silicon oxynitride film is formed by introducing nitrogen atoms into the silicon oxide film using a nitriding treatment. Concentration distributions of the oxygen and nitrogen atoms in the silicon oxynitride film in a thickness direction thereof as measured using a SIMS (Secondary Ion Mass Spectrometory) method are shown in dotted lines (before oxidation treatment) of FIG. 1. In FIG. 1, the silicon substrate is identified as a region which contacts with the gate insulating film and has the oxygen atoms concentration of 0 atom % when the oxygen atoms concentration is measured using the SIMS method. At a top section of FIG. 1, the gate insulating film and silicon substrate are shown based on oxygen concentration distributions before the oxidation treatment.

Next, in order to terminate dangling-bond of silicon in the surface of the silicon oxynitride film, the oxidation treatment is carried out to form the gate insulating film. A low pressure dry oxidation treatment is generally performed as the oxidation treatment. The low pressure dry oxidation treatment uses, for example, following conditions:
Process gas and flow rate: N₂/O₂=1000/1000 sccm
Heating temperature: 800 to 1100° C.
Pressure: 1 to 10 Torr

At this time, concentration distributions of the oxygen and nitrogen atoms in the silicon oxynitride film in the thickness direction after the low pressure dry oxidation treatment as measured using a SIMS method are shown in solid lines (after the oxidation treatment) of FIG. 1. As shown in FIG. 1, the concentration distributions of the oxygen and nitrogen atoms in the silicon oxynitride film in the thickness direction vary with the low pressure dry oxidation treatment. It is confirmed from FIG. 1 that the nitrogen atoms included in the silicon oxynitride film entirely shift toward the silicon substrate. It appears in FIG. 1 that a shift distance of the nitrogen atoms is approximately 0.1 nm at about the surface of the silicon oxynitride film (about 0.1 nm point in a lateral axis) while that is approximately 0.5 nm at about a boundary between the silicon oxynitride film and the silicon substrate (about 0.9 nm point in the lateral axis). Moreover, the nitrogen atoms exist in the region at which the oxygen atom concentration is 0 atom %, and, hence, it is confirmed that the nitrogen atoms diffuse into the silicon substrate.

This is because it is believed that in the low pressure dry oxidation treatment, nitrogen and oxygen atoms do not react with each other and then the nitrogen atoms diffuse into the silicon substrate together with the diffusion of the oxygen atoms, so that nitrogen and oxygen atoms entirely shift toward the silicon substrate. Moreover, this is because it is believed that the diffusion rate of nitrogen atoms is larger than the diffusion rate of oxygen atoms at about the boundary between the gate insulating film and the silicon substrate.

### SUMMARY OF THE INVENTION

In one embodiment, there is provided a method for manufacturing a semiconductor device including a transistor, comprising:

forming a silicon oxide film on a semiconductor layer;

performing a plasma nitriding treatment to the silicon oxide film to introduce nitrogen atoms into the silicon oxide film;

performing a radical oxidation treatment to the nitrogen atoms introduced silicon oxide film so that the nitrogen atoms introduced silicon oxide film does not contain the nitrogen atom in a first face thereof being in a contact with the semiconductor layer and in a second face thereof being surface of the nitrogen atoms introduced silicon oxide film, and a peak of nitrogen atom concentration appears between the first and second faces in the nitrogen atoms introduced silicon oxide film, thereby forming a gate insulating film;

forming a gate electrode on the gate insulating film; and

forming source and drain regions in semiconductor layer positioned in opposite sides which sandwiches the gate electrode.

### BRIEF DESCRIPTION OF THE ACCOMPANYING DRAWINGS

The above features and advantages of the present invention will be more apparent from the following description of certain preferred embodiments taken in conjunction with the accompanying drawings, in which:

FIG. 1 is a graph illustrating concentration distributions of oxygen and nitrogen atoms in a conventional gate insulating film in a thickness direction thereof;

FIGS. 2 and 3 illustrates a method for manufacturing one exemplary embodiment of a semiconductor device according to the invention;

FIG. 4 is a graph illustrating concentration distributions of oxygen and nitrogen atoms in a gate insulating film according to the invention in a thickness direction thereof; and

FIG. 5 is a graph illustrating concentration distributions of oxygen and nitrogen atoms in a gate insulating film according to the invention in a thickness direction thereof.

In the drawings, numerals have the following meanings. 1: silicon substrate, 2: silicon oxide film, 3: silicon oxynitride film, 4, 5, 6: gate electrode, 7: etching mask layer, 8: side wall film, 9: interlayer insulating film, 10: first face, 11: second face

### DETAILED DESCRIPTION OF THE EXEMPLARY EMBODIMENT

The semiconductor device includes a transistor. A gate insulating film of the transistor contains oxygen and nitrogen atoms, and the gate insulating film includes a first face being in a contact with a semiconductor layer and a second face being in a contact with a gate electrode. The gate insulating film does not contain the nitrogen atoms in about the first and second faces, and a peak of the nitrogen atoms concentration as measured using a SIMS method appears between the first and second faces.

In this way, the gate insulating film does not contain the nitrogen atoms in about the first face, and, hence, there are none of the nitrogen atoms diffusing into the semiconductor layer. As a result, characteristic deterioration of the transistor may be suppressed. Otherwise, the characteristic deterioration of the transistor may occur when there are generated fixed charges due to the nitrogen atoms existing in the semiconductor layer. Moreover, the gate insulating film does not contain the nitrogen atoms in about the second face, and, hence, charges concentrating due to the nitrogen atoms and thus electric-field concentrating may be suppressed.

Meanwhile, “a gate insulating film” used herein and claims refers to a layer which is in a contact with the gate electrode and contains the oxygen and nitrogen atoms. Some regions in the gate insulating film may not contain the nitrogen atoms. “A semiconductor layer” used herein and claims refers to a region which is in a contact with the gate insulating film and in which concentration of the oxygen atoms as measured using the SIMS method becomes 0 atom %. Therefore, when oxygen atoms diffuse to the semiconductor layer side with a radical oxidation treatment, the semiconductor layer and gate insulating film occupying regions and thus the first face between them have shifted. A silicon substrate is generally employed as the semiconductor layer.

The invention will be now described herein with reference to illustrative embodiments. Those skilled in the art will recognize that many alternative embodiments can be accomplished using the teachings of the present invention and that the invention is not limited to the embodiments illustrated for explanatory purpose.

### First Exemplary Embodiment

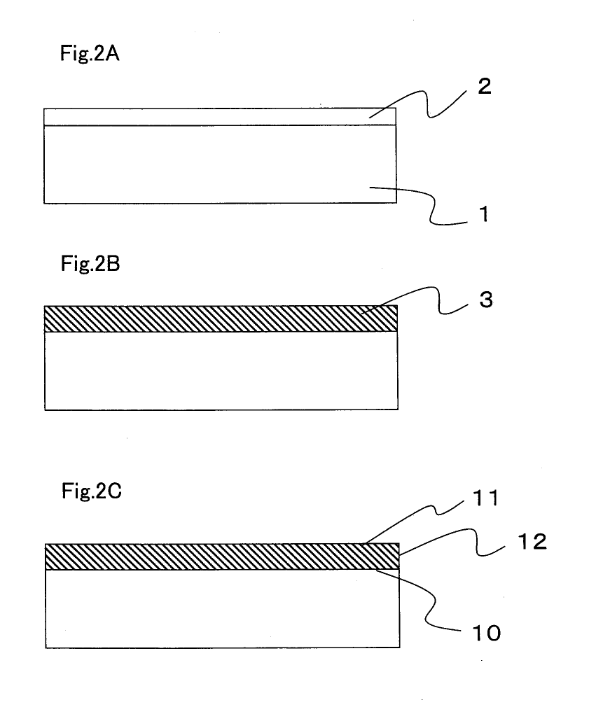

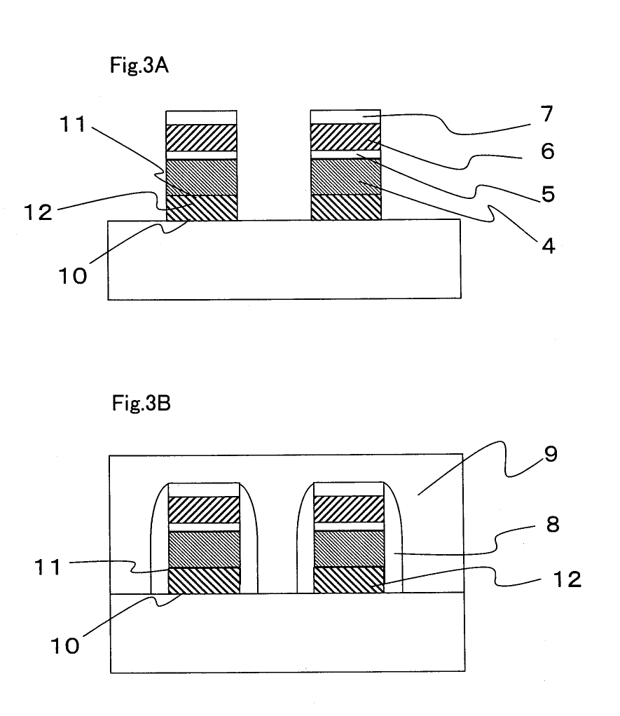

Below, a method for manufacturing a semiconductor device according to the first exemplary embodiment will be described with reference to FIG. 2 and FIG. 3. As show in FIG. 2A, first, silicon oxide film 2 with 1.1 nm thickness is formed on silicon substrate 1 (corresponding to the semiconductor layer) using a thermal oxidation method. Here, the thermal oxidation method is preferably the radical oxidation treatment. For example, the thermal oxidation method is carried out at heating temperature 1050° C. using oxygen and nitrogen gases as process gas.

Next, as shown in FIG. 2B, silicon oxide film is subjected to a plasma nitriding treatment under following conditions:
Apparatus name: Trias SPA (Slot Plane Antenna) available from Tokyo Electron Limited (TEL)
Process gas name and flow rate: N₂/Ar=1000/1000 sccm
Power: 1000 to 3000 W
Pressure: equal to or lower than 1 Torr
Wafer temperature: 400° C.

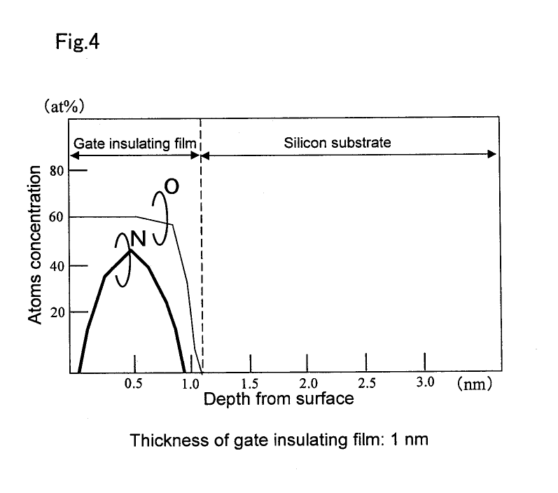

In this way, silicon oxynitride film 3 is formed which includes a nitride distribution layer (a mixture layer of silicon nitride [SiN], nitrogen oxide [NO] or the like) in silicon oxide film 2. FIG. 4 is a graph illustrating concentration distributions of the oxygen (O) and nitrogen (N) atoms in the silicon oxynitride film with the 1.1 nm thickness formed by the plasma nitriding treatment as measured in a thickness direction thereof with the SIMS method.

It is known from FIG. 4 that there are none of the nitrogen atoms at about both side faces (at an about 0 nm point and an about 1.1 nm point in the lateral axis) of silicon oxynitride film 3 having thickness of about 1.1 nm, and a peak value of 45 atom % of the nitrogen atom concentration appears between the both side faces. Furthermore, It is known from FIG. 4 that the oxygen atom concentration in silicon oxynitride film 3 becomes substantially constant as 60 atom %, while the oxygen atom concentration decreases rapidly in about the boundary face (the first face) between silicon substrate 1 and silicon oxynitride film 3.

With the plasma nitriding treatment, silicon oxynitride film 3 is exposed to plasma and thus dangling bond of silicon is formed in a surface thereof. For this reason, as shown in FIG. 2C, the dangling bond is terminated with oxygen atoms by performing the radical oxidation treatment under following conditions:
Process gas name and flow rate: H₂/O₂=400 sccm/19600 sccm
Heating temperature: 800 to 1100° C.
Pressure: 1 to 10 Torr.

With the radical oxidation treatment, the dangling bond is terminated and at the same time the oxygen atoms diffuse into silicon oxynitride film 3. The diffused oxygen atoms oxidize silicon oxynitride film 3 so as to make oxidized silicon oxynitride film 3 gate insulating film 12, and, then, reach silicon substrate 1 to oxidize silicon substrate 1.

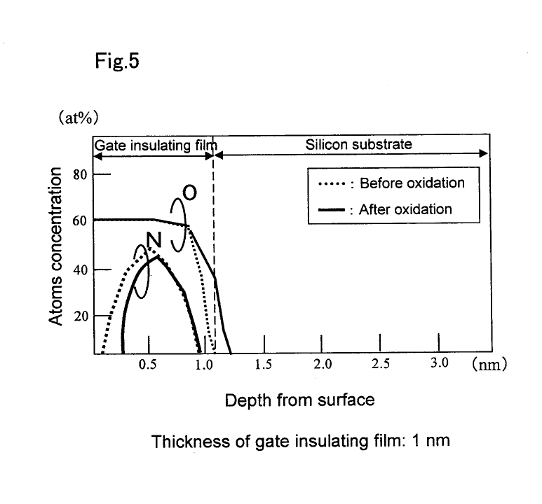

FIG. 5 is a graph illustrating, as solid lines, concentration distributions of the oxygen (O) and nitrogen (N) atoms in gate insulating film 12 with 1.2 nm thickness formed by the plasma nitriding treatment and then the radical oxidation treatment, as measured in a thickness direction thereof with the SIMS method. Meanwhile, at a top section of FIG. 5, the gate insulating film and silicon substrate are shown based on oxygen concentration distributions before the radical oxidation treatment. It is known from FIG. 5 that a peak value of 40 atom % of the nitrogen atom concentration appears at an about 0.5 nm point in the lateral axis.

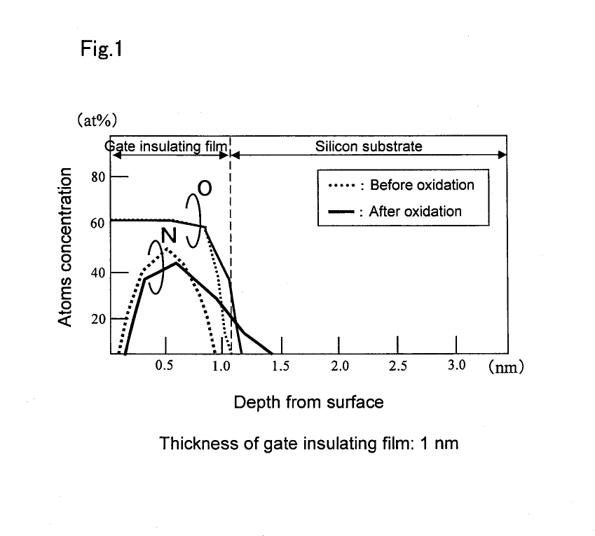

Here, the nitrogen atom concentration in silicon oxynitride film 3 shifts by about 0.15 nm toward silicon substrate 1 only at about the surface (at an about 0.1 nm point in the lateral axis) of gate insulating film 12. For this reason, in the gate insulating film, there are none of the nitrogen atoms in a region from its surface (the second face: at 0 nm point in the lateral axis) to 0.25 nm point from the surface. Moreover, the nitrogen atoms in the gate insulating film at about the boundary face between film 12 and substrate 1 do not diffuse toward silicon substrate 1. Accordingly, in the gate insulating film, there are none of the nitrogen atoms in a region from the boundary face (the first face: at an about 1.2 nm point in the lateral axis) to 0.25 nm point from the boundary face. The film thickness of the gate insulating film becomes 1.2 nm after the radical oxidation treatment. In case the film thickness of the gate insulating film becomes equal to or smaller than 1.2 nm after the radical oxidation treatment, the nitrogen atoms are easy to diffuse into the silicon substrate not containing the oxygen atoms, as shown in FIG. 1, especially using the conventional low pressure dry oxidation treatment. To the contrary, in this embodiment, the concentration distribution of the nitrogen atoms in the gate insulating film at about the boundary face with the silicon substrate does not change, and, hence, the nitrogen atoms may not diffuse into the silicon substrate. Accordingly, the fixed charges are effectively prevented from appearing in the silicon substrate.

This is because it is believed that in the radical oxidation treatment, the oxygen atom is in a radical state and thus has a stronger oxidation effect than in the conventional low pressure dry oxidation treatment, so that the oxygen atoms diffuse into the silicon oxynitride film and then react with the nitrides of the silicon oxynitride film. Further, it is believed that the oxygen atom reacting with the nitrides or the nitrogen atom always exists at about the surface of the silicon oxynitride film, and, thus, the distribution of the nitrogen atoms only at about the surface of the silicon oxynitride film shift.

Consequently, in the radical oxidation treatment, the nitrogen atoms may not diffuse into the silicon substrate differently from in the conventional low pressure dry oxidation treatment, and, hence, the fixed charges causing defects in the silicon substrate are prevented from appearing in the silicon substrate.

As shown in FIG. 3A, on gate insulating film 12, a polysilicon film as gate electrode 4, a tungsten silicide film as gate electrode 5 and a tungsten film as gate electrode 6 are stacked in this order. Further, a silicon nitride film as etching mask layer 7 is formed and then a gate pattern is formed by performing photolithography and dry etching techniques using etching mask layer 7. For example, in a P type channel transistor, boron (B) atoms are doped into the polysilicon film.

As shown in FIG. 3B, a silicon nitride film is formed on etching mask layer 7 and then is etched back so that side wall film 8 made of the silicon nitride film is formed only on the side wall of the gate pattern, thereby completing a transistor.

As mentioned above, in this transistor, there are none of the nitrogen atoms in silicon substrate 1, and, therefore, the fixed charges causing defects in the silicon substrate 1 are prevented from appearing in the silicon substrate. Accordingly, the characteristic deterioration of the transistor may be suppressed. Moreover, the charges concentrating due to the nitrogen atoms existing in the gate insulating film may be avoided; or the problem that the gate insulting film has a high dielectric constant locally due to the nitrogen atoms existing in the gate insulating film may be avoided. For those reasons, the electric-field concentrating in the boundary face between the gate insulating film and gate electrode may be suppressed. As a result, the transistor with superior reliability may be acquired.

Interlayer insulating film 9 is formed on an entire surface of the transistor so as to fill the gate pattern, and, then, is planarized with a CMP (chemical Mechanical Polishing) method. A bit line (not shown) is formed to connect to one of source and drain regions while a capacitor (not shown) is formed to connect to the other of the source and drain regions. In this way, there is formed a DRAM (dynamic random access memory) device including a cell having the capacitor and transistor.

It is apparent that the present invention is not limited to the above embodiments, but may be modified and changed without departing from the scope and spirit of the invention.

In addition, while not specifically claimed in the claim section, the applications reserve the right to include in the claim section at any appropriate time the following data processing systems:

1. A semiconductor device including a transistor, comprising:

a semiconductor layer;

a gate insulating film formed on the semiconductor layer;

a gate electrode formed on the gate insulating film; and

source and drain regions formed in the semiconductor layer,

wherein the gate insulating film contains oxygen and nitrogen atoms,

the gate insulating film does not contain the nitrogen atom in a first face thereof being in a contact with the semiconductor layer, and in a second face thereof being in a contact with the gate electrode, and

a peak of nitrogen atom concentration appears between the first and second faces in the gate insulating film.

2. The semiconductor device according to the above 1, further comprising:

a bit line connected to one of the source and drain regions; and

a capacitor connected to the other of the source and drain regions,

wherein the semiconductor device is dynamic random access memory.

3. The semiconductor device according to the above 1,

wherein the gate insulating film is a silicon oxynitride film.

4. The semiconductor device according to the above 1,

wherein a film thickness of the gate insulating film is equal to or smaller than 1.2 nm.

5. The semiconductor device according to the above 1,

wherein the gate insulating film does not contain the nitrogen atom in a region from the first face to 0.25 nm point from the first face in a thickness direction thereof.

6. The semiconductor device according to the above 1,

wherein the gate insulating film does not contain the nitrogen atom in a region from the second face to 0.25 nm point from the second face in a thickness direction thereof.

7. The semiconductor device according to the above 1,

wherein the semiconductor layer does not contain the nitrogen atom, in case of measuring the semiconductor layer using a Secondary Ion Mass Spectrometory.

What is claimed is:

1. A method for manufacturing a semiconductor device including a transistor, comprising:
forming a silicon oxide film on a semiconductor layer;
performing a plasma nitriding treatment to the silicon oxide film to introduce nitrogen atoms into the silicon oxide film;
performing a radical oxidation treatment to the nitrogen atoms introduced silicon oxide film so that the nitrogen atoms introduced silicon oxide film does not contain the nitrogen atom in a first face thereof being in a contact with the semiconductor layer and in a second face thereof being surface of the nitrogen atoms introduced silicon oxide film, and a peak of nitrogen atom concentration appears between the first and second faces in the nitrogen atoms introduced silicon oxide film, thereby forming a gate insulating film;
forming a gate electrode on the gate insulating film; and
forming source and drain regions in semiconductor layer positioned in opposite sides which sandwiches the gate electrode.

2. The method according to claim 1, further comprising:
forming a bit line so as to be electrically connected to one of the source and drain regions; and
forming a capacitor so as to be electrically connected to the other of the source and drain regions,
wherein the semiconductor device is dynamic random access memory.

3. The method according to claim 1,
wherein the gate insulating film is a silicon oxynitride film.

4. The method according to claim 1,
wherein a film thickness of the gate insulating film is equal to or smaller than 1.2 nm.

5. The method according to claim 1,
wherein the radical oxidation treatment is performed so that the gate insulating film does not contain the nitrogen atom in a region from the first face to 0.25 nm point from the first face in a thickness direction thereof.

6. The method according to claim 1,
wherein the radical oxidation treatment is performed so that the gate insulating film does not contain the nitrogen atom in a region from the second face to 0.25 nm point from the second face in a thickness direction thereof.

7. The method according to claim 1,
wherein the radical oxidation treatment is performed under temperature of 800 to 1100° C. and pressure of 1 to 10 Torr using a mixed gas of H₂/O₂=400 sccm/19600 sccm.

8. The method according to claim 1,
wherein the radical oxidation treatment is performed so that the semiconductor layer does not contain the nitrogen atom, in case of measuring the semiconductor layer using a Secondary Ion Mass Spectrometory.
